(19) United States
(12) Patent Application Publication
(10) Pub. No.: US 2008/0174008 A1
(43) Pub. Date: Jul. 24, 2008

(54) Structure of Memory Card and the Method of the Same

(76) Inventors: Wen-Kun Yang, Hsin-Chu City (TW); Chun-Hui Yu, Tainan County (TW); Chihwei Lin, Tainan County (TW); Chao-nan Chou, Taipei City (TW)

Correspondence Address: THE MAXHAM FIRM, 9330 SCRANTON ROAD, SUITE 350, SAN DIEGO, CA, 92121, US

(21) Appl. No.: 11/624,629

(22) Filed: Jan. 18, 2007

(51) Int. Cl. H01L 25/065; H01L 21/50

(52) U.S. Cl. 257/723; 438/108; 438/109; 257/E25.013; 257/E23.008; 257/E23.009; 257/E23.031; 257/E21.51; 257/E21.511

(57) ABSTRACT

The present invention provides a structure of memory card comprising a substrate with a die receiving cavity formed within an upper surface of the substrate and a through hole structure formed there through, traces formed within the substrate; a first die disposed within the die receiving cavity; a first dielectric layer formed on the first die and the substrate; a first re-distribution layer (RDL) formed on the first dielectric layer, wherein the first RDL is coupled to the first die and the traces; a second dielectric layer formed over the first RDL; a second die disposed on the second dielectric layer; a third dielectric layer formed over the second dielectric layer and the second die; a second RDL formed on the third dielectric layer, wherein the second RDL is coupled to the second die and the first RDL; a forth dielectric layer formed over the second RDL; a third die formed over the forth dielectric layer and coupled to the second RDL; a fifth dielectric layer formed around the third die; and a plastic cover enclosed the first, second and third dice.

### FIELD OF THE INVENTION

This invention relates to a structure of memory card, and more particularly to a memory card having a substrate with die receiving cavity to receive a die.

### DESCRIPTION OF THE PRIOR ART

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip.

One product called Electronic circuit cards is provided along with development of the semiconductor. Memory cards are used with personal computers, cellular telephones, personal digital assistants, digital still cameras, digital movie cameras, portable audio players and other devices for data storage. The development of the many electronic card standards has created different types of. An electrical connector is provided along a narrow edge of the card.

A memory card is an extension card that can be inserted into a host device. The memory card characteristically provides high speed access and large memory capacity. Recently, memory cards having Giga-Bytes memory capacity have been developed. There are various types of memory cards that are currently available. The flash memory card can be erased through electrical processing. Thus, the flash memory can be used as an alternative of a hard disc drive in a portable computer. The flash memory card has been widely used to store and reproduce data in devices.

FIG. 1 provides some conventional types of memory card. The disadvantages of the prior art includes: it is hard to provide the thinner package by using wire bonding due to the wire bonding profile. It is unlikely to provide the thinner package by WIB stacking due to it needs the spacer between die stacking and it needs the molding to protect the chips and wires. The process includes molding injection or liquid printing. It raises the yield concern issue. The micro SD card requests the total thickness is 0.7 mm+/−0.1 mm.

Therefore, what is required is an advance memory card structure to reduce the package thickness with simple process to overcome the aforementioned.

### SUMMARY OF THE INVENTION

One object of the present invention is to provide a super thin and small form factor memory card.

Another object of the present invention is to provide a high reliability product with simple process and low cost solution.

A structure of memory card comprises a substrate with a die receiving cavity formed within an upper surface of the substrate and a through hole structure formed there through, traces formed within the substrate; a first die disposed within the die receiving cavity; a first dielectric layer formed on the first die and the substrate; a first re-distribution layer (RDL) formed on the first dielectric layer, wherein the first RDL is coupled to the first die and the traces; a second dielectric layer formed over the first RDL; a second die disposed on the second dielectric layer; a third dielectric layer formed over the second dielectric layer and the second die; a second RDL formed on the third dielectric layer, wherein the second RDL is coupled to the second die and the first RDL; a forth dielectric layer formed over the second RDL; a third die formed over the forth dielectric layer and coupled to the second RDL; a fifth dielectric layer formed around the third die (optional process for using the flip chip type of third die); and a plastic cover enclosed the first, second and third dice.

The further comprises passive device formed on said forth dielectric layer. In one case, the third die is formed by flip chip configuration. Alternatively, the third die is attached on said forth dielectric layer, and a third RDL is formed over said fifth dielectric layer and coupled to said second RDL.

One of the first, second, third, forth and the fifth dielectric layers includes an elastic dielectric layer. One of the first, second, third, forth and the fifth dielectric layers comprises a silicone dielectric based material, BCB or PI. The silicone dielectric based material comprises siloxane polymers (SINR), silicon oxide, silicon nitride, or composites thereof. One of the first, second, third, forth and the fifth dielectric layers comprises a photosensitive layer. The first and second RDLs fan out from the first and second dice.

### BRIEF DESCRIPTION OF THE DRAWINGS

FIG. 1 illustrates a cross-sectional view of a structure of memory card according to the prior art.

FIG. 2 illustrates a cross-sectional view of a substrate structure according to the present invention.

FIG. 3 illustrates a cross-sectional view of a structure according to the present invention.

FIG. 4 illustrates a cross-sectional view of a structure according to the present invention.

FIG. 5(a)-(i) illustrates a flow chart of manufacturing of the memory card according to the present invention.

FIG. 6 illustrates a cross-sectional view of a structure according to the present invention.

FIG. 7 illustrates a cross-sectional view of a structure according to the present invention.

FIG. 8 illustrates a cross-sectional view of a structure according to the present invention.

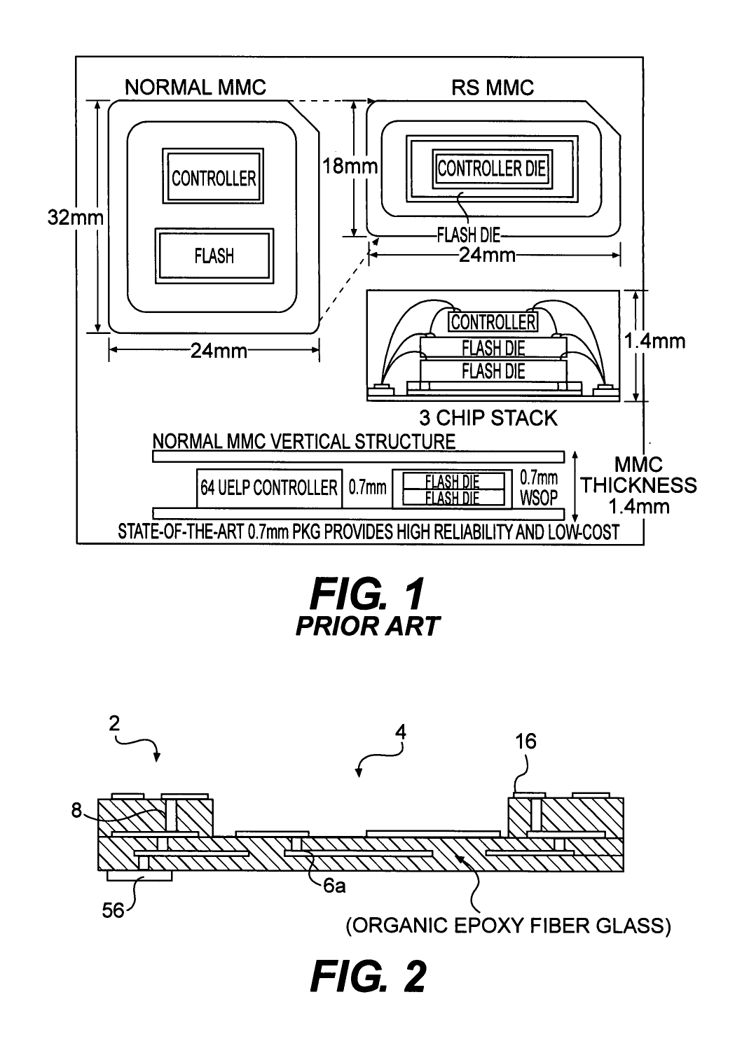

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

The present invention discloses a structure of WLP utilizing a substrate having predetermined cavity and through holes formed into the substrate. A photosensitive material is coated over the die and the pre-formed substrate. Preferably, the material of the photosensitive material is formed of elastic material.

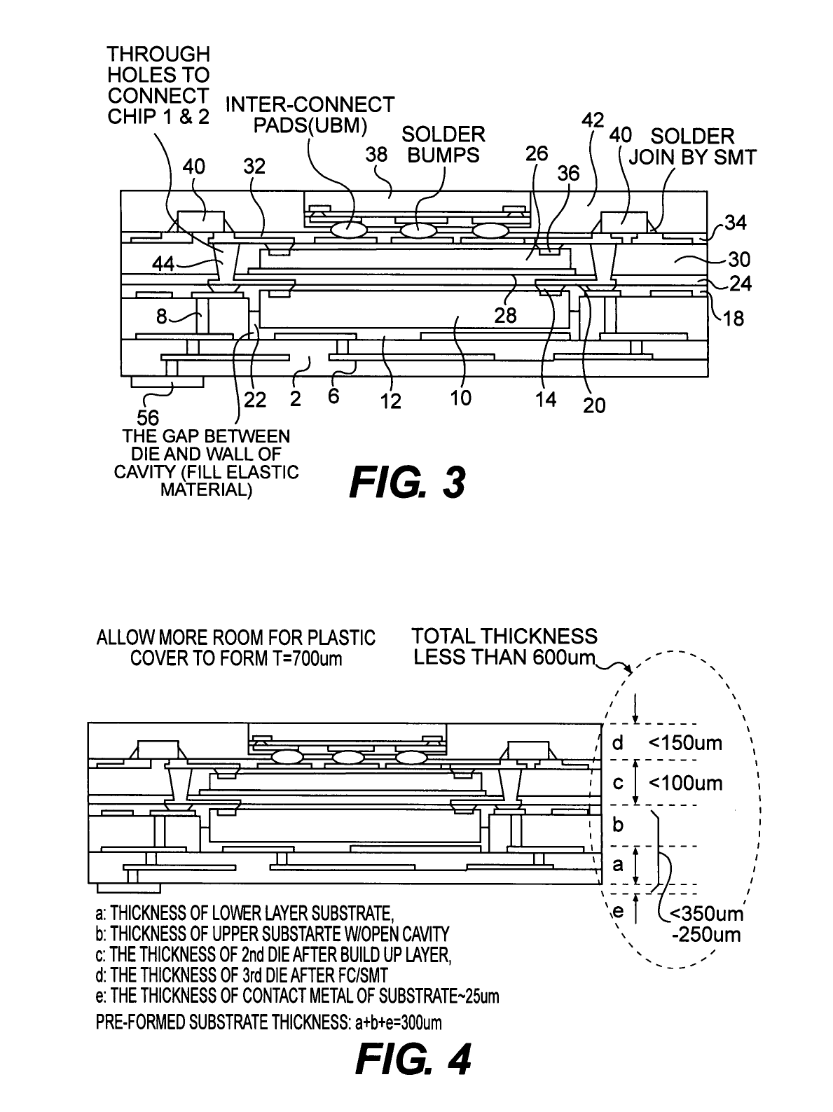

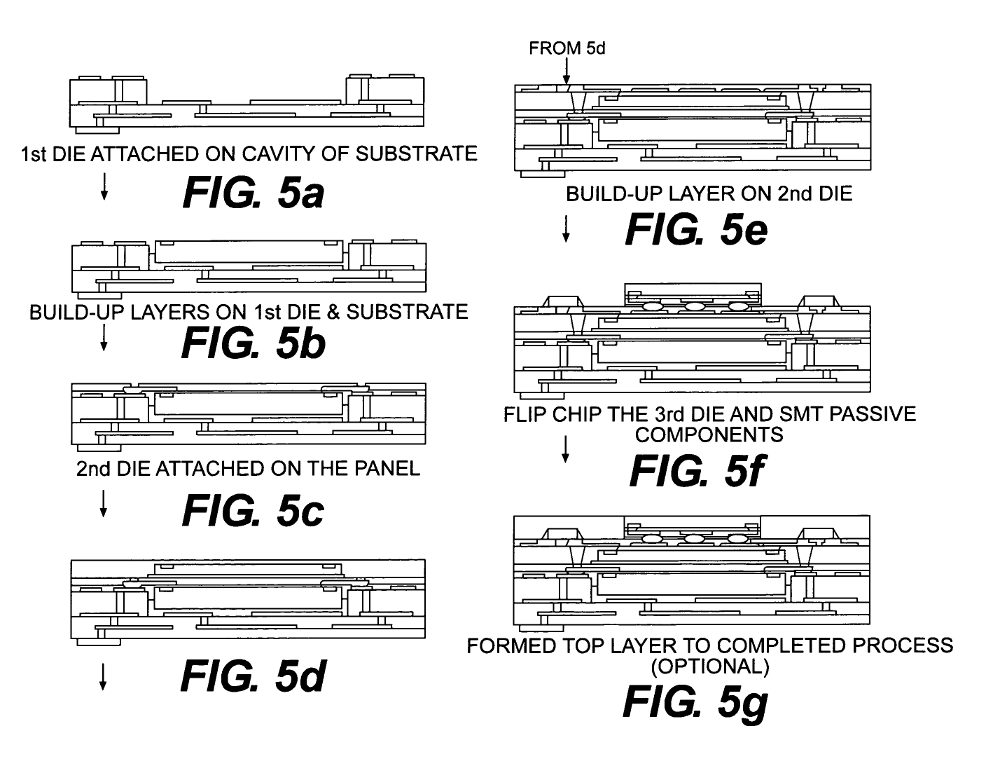

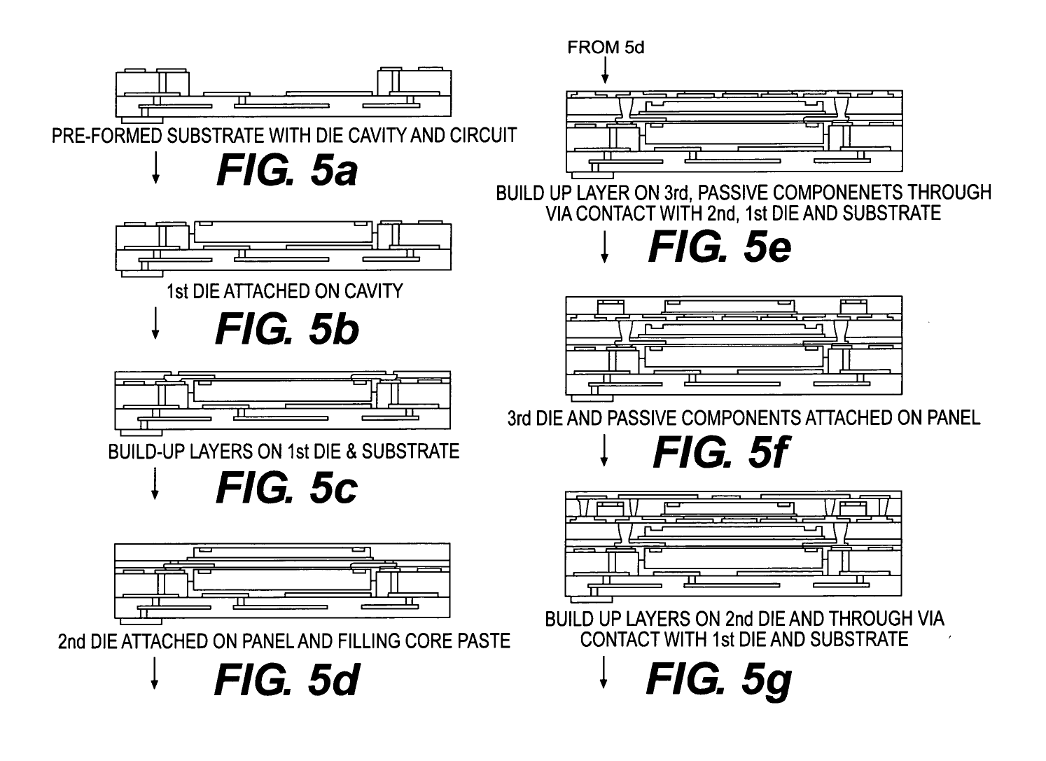

FIG. 2 illustrates the pre-formed substrate and FIG. 3, 4 illustrates structure of the memory card and FIG. 5 illustrates the process flow in accordance with one embodiment of the present invention. As shown in the FIGS. 2, 3 and 5(a), the structure includes a substrate 2 having a die receiving cavity 4 formed therein to receive a die. Pluralities of through holes 8 and traces 6 are created within or on the substrate 2. The through holes 8 are formed from upper surface to lower surface of the substrate 2. A conductive material will be re-filled into the through holes 8 for electrical communication. A terminal pad 56 is formed at the lower surface of the substrate 2.

A first die 10 is disposed within the die receiving cavity 4 on the substrate 2 and fixed by an adhesion material 12. As know, contact pads (Bonding pads) 14 are formed on the die 10 and pads 16 are on the substrate 2. The gap between the die and the sidewall of the cavity 4 is filled with filling material 22, it maybe the same as the adhesion material 12. A photosensitive layer or dielectric layer 18 is formed over the die and filling into the space between the die 10 and the walls of the cavity 4 (for keeping the same surface level). Pluralities of openings are formed within the dielectric layer 18 through the lithography process or exposure procedure. The pluralities of openings are aligned to the contact via through holes 8 and the contact or I/O pads 14, respectively. The RDL (re-distribution layer) 20, also referred to as metal trace, is formed on the dielectric layer 18 by removing selected portions of metal layer formed over the layer 18, wherein the RDL 20 keeps electrically connected with the die 10 through the I/O pads 14. A part of the material of the RDL will re-fills into the openings in the dielectric layer 18, thereby forming contact via metal over the through holes 8 and pad metal over the pad 16. Another dielectric layer 24 is formed to cover the RDL 20, as shown in FIGS. 3 and 5(c).

Please refer to FIGS. 3 and 5(d)-(e), the dielectric layer 18 is formed atop of the die 10 and substrate and fills the space surrounding the die 2. A second die 26 is attached on the second dielectric layer 24 via the adhesive material 28. Similarly, the third dielectric layer or photosensitive layer 30 is formed over the second die 26 and filling into the space adjacent to the die 26. Pluralities of openings arc formed within the dielectric layer 30 through the lithography process or exposure procedure. The pluralities of openings are aligned to the contact via 110 pads 36 of the second die 26, respectively. A second RDL (re-distribution layer) 32 is formed on the third dielectric layer 30 by removing selected portions of metal layer formed over the layer, wherein the RDL 32 keeps electrically connected with the second die 26 through the I/O pads 26. A forth dielectric layer 34 covers the second RDL (re-distribution layer) 32. Pluralities of openings are formed within the forth dielectric layer 34.

Please refer to the FIGS. 3 and 5 (f)-(g), a third die 38 are attached on the forth dielectric layer 34 and coupled to the second RDL (re-distribution layer) 32 through the openings of the forth dielectric layer 34 and the bumps of the third die 38. Preferably, the third die 38 is coupled by the way of flip chip configuration. Further, at least one passive device 40 may be coupled to the second RDL 32 by SMT (surface mounting technology). Finally, a top layer 42 is formed to cover the passive device 40 and at least surrounding the third die 38 (it is an optional process for the present invention). In one case, the upper surface of the die 38 can be exposed for reducing the thickness and thermal dissipation. The second RDL 32 is communicated to the first RDL 20 through the through-hole structure 44.

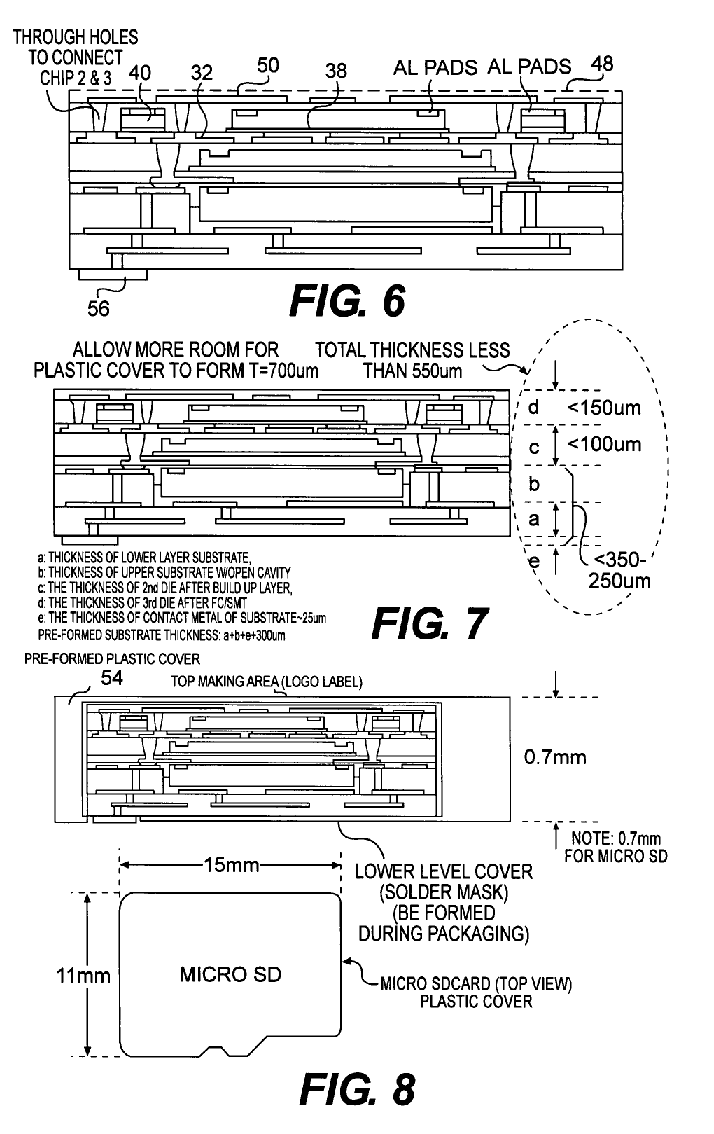

Alternatively, FIGS. 6 and 5(h)-(i), the third die 38 is attached over the second RDL by adhesive material 46, not by flip chip configuration. A fifth dielectric layer 48 is formed to cover the passive device 40 and the third die 38. A third RDL 50 is formed on the fifth dielectric layer 48 and connected to the third die, passive device and the second RDL 32. A top layer 52 is formed over the third RDL 50, as shown in FIG. 5(h)-(i). The other structures are similar to FIG. 5 (a)-(e). The description is omitted. FIG. 4 and FIG. 7 indicate the dimension of the memory card structure. From the illustration, the dimension is much thinner than the prior art.

FIG. 8 illustrate the final scheme of the memory card. A pre-formed plastic cover 54 encloses the multi-die. The top marking may be formed on the upper cover and solder mask is formed under the package structure to expose the terminal pads 56.

Preferably, the material of the substrate 2 is organic substrate likes FR5, BT, FR4, PCB with defined cavity or Alloy42 with pre etching circuit. The organic substrate with high Glass transition temperature (Tg) are epoxy type FR5 or BT (Bismaleimide triazine) type substrate. The Alloy42 is composed of 42% Ni and 58% Fe. Kovar can be used also, and it is composed of 29% Ni, 17% Co, 54% Fe. The glass, ceramic, silicon can be used as the substrate. The depth of the cavity 4 could be little thick than the thickness of the die 10. It could be deeper as well.

The substrate could be round type such as wafer type, the diameter could be 200, 300 mm or higher. It could be employed for rectangular type such as panel form. In one embodiment of the present invention, these dielectric layers in the present invention could be preferably an elastic dielectric material which is made by silicone dielectric materials comprising siloxane polymers (SINR), silicon oxide, silicon nitride, and composites thereof. In another embodiment, the dielectric layer is made by a material comprising benzocyclobutene (BCB), epoxy, polyimides (PI) or resin. Preferably, it is a photosensitive layer for simple process.

In one embodiment of the present invention, the elastic dielectric layer is a kind of material with CTE larger than 100 (ppm/° C.), elongation rate about 40 percent (preferably 30 percent-50 percent), and the hardness of the material is between plastic and rubber. The thickness of the elastic dielectric layer 18 depends on the stress accumulated in the RDL/dielectric layer interface during temperature cycling test.

In one embodiment of the invention, the material of the RDL comprises Ti/Cu/Au alloy or Ti/Cu/Ni/Au alloy; the thickness of the RDL is between 2 um_and_{—}15 um. The Ti/Cu alloy is formed by sputtering technique also as seed metal layers, and the Cu/Au or Cu/Ni/Au alloy is formed by electroplating; exploiting the electroplating process to form the RDL can make the RDL thick enough to withstand CTE mismatching during temperature cycling. The metal pads can be Al or Cu or combination thereof.

As shown in FIG. 2(a)-(g), the RDL fans out of the die and the communication downwardly toward the traces 6. The communication traces are penetrates through the substrate 2 via the through holes 8. Therefore, the thickness of the die package maybe shrinkage. The package of the present invention will be thinner than the prior art. Further, the substrate is pre-prepared before package. The cavity 4 and the traces 6 are pre-determined as well. Thus, the throughput will be improved than ever. The present invention discloses a fan-out WLP without stacked built-up layers over the RDL.

The Advantages of the Present Invention are:

Super thin package and small form factor: The thickness of package is around 450 um to 600 um and the form factor can be slight large than chip size. It is easy to control the total card thickness after mounting the plastic cover as final product. The thickness of dice can be controlled 100 um to 50 um and higher density of memory can be achieved by stacking die within package.

Higher Reliability product: the chips are fully packaged inside the package. At least 100 um thick epoxy materials are formed on both side of chips. The chips is within the cavity and the elastic materials filling surrounding the chip between the wall of cavity to absorb the mechanical stress due to CTE mismatching between chips and substrate (FR5 CTE around 17 to 20). Further, the dielectric layer materials are elastic to absorb the mechanical stress during temperature cycling. The chips can be stacked on the first chip, the CTE mismatching issue is eliminated.

Simple process and low cost solution: The present invention employs substrate (FR5) with cavity and circuit formed therein. Build-up layers process are used to manufacturing the “package” by piece panel or batch type. The die is attached by the panel bonding process to provide higher accuracy. The packages are separated by using the dicing saw process to separate the “Package”. A pre-formed plastic cover is introduced to form the final product. The present invention can be used to test the FGS product by panel level to reduce the testing cost.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A structure of memory card comprising:
a substrate with a die receiving cavity formed within an upper surface of said substrate and a through hole structure formed there through, traces formed within said substrate;
a first die disposed within said die receiving cavity;
a first dielectric layer formed on said first die and said substrate;
a first re-distribution layer (RDL) formed on said first dielectric layer, wherein said first RDL is coupled to said first die and said traces;
a second dielectric layer formed over said first RDL;
a second die disposed on said second dielectric layer;
a third dielectric layer formed over said second dielectric layer and said second die;
a second RDL formed on said third dielectric layer, wherein said second RDL is coupled to said second die and said first RDL;
a forth dielectric layer formed over said second RDL;
a third die formed over said forth dielectric layer and coupled to said second RDL;
a fifth dielectric layer formed around said third die; and
a plastic cover enclosed said first, second and third dice.

2. The structure of claim 1, further comprising passive device formed on said forth dielectric layer.

3. The structure of claim 1, wherein said third die is formed by flip chip configuration.

4. The structure of claim 1, wherein said third die is attached on said forth dielectric layer, and a third RDL is formed over said fifth dielectric layer and coupled to said second RDL.

5. The structure of claim 1, wherein one of said first, second, third, forth and fifth dielectric layers includes an elastic dielectric layer

6. The structure of claim 1, wherein one of said first, second, third, forth and fifth dielectric layers comprises a silicone dielectric based material, BCB or PI.

7. The structure of claim 6, wherein said silicone dielectric based material comprises siloxane polymers (SINR), silicon oxide, silicon nitride, or composites thereof.

8. The structure of claim 1, wherein one of said first, second, third, forth and fifth dielectric layers comprises a photosensitive layer.

9. The structure of claim 1, wherein one of said first and second RDL is made from an alloy comprising Ti/Cu/Au alloy or Ti/Cu/Ni/Au alloy.

10. The structure of claim 1, wherein said first and second RDLs fan out from said first and second dice.

11. The structure of claim 1, wherein the material of said substrate includes epoxy type FR5 or FR4.

12. The structure of claim 1, wherein the material of said substrate includes BT.

13. The structure of claim 1, wherein the material of said substrate includes PCB (print circuit board).

14. The structure of claim 1, wherein the material of said substrate includes alloy or metal.

15. The structure of claim 14, wherein the material of said substrate includes Alloy42 (42% Ni-58% Fe) or Kovar (29% Ni-17% Co-54% Fe).

16. The structure of claim 1, wherein the material of said substrate includes glass.

17. The structure of claim 1, wherein the material of said substrate includes silicon.

18. The structure of claim 1, wherein the material of said substrate includes ceramic.

19. A method for forming semiconductor device package comprising:
providing a substrate with a die receiving cavity formed within an upper surface of said substrate and a through hole structure formed there through, wherein a conductive trace formed on or within said substrate;
providing a first die disposed within said die receiving cavity;
forming a first dielectric layer over said first die and said substrate;
forming a first re-distribution layer (RDL) on said first dielectric layer, wherein said first RDL is coupled to said first die and said traces;
forming a second dielectric layer over said first RDL;
forming a second die disposed on said second dielectric layer;
forming a third dielectric layer over said second dielectric layer and said second die;
forming a second RDL formed on said third dielectric layer, wherein said second RDL is coupled to said second die and said first RDL;
forming a forth dielectric layer formed over said second RDL;
providing a third die over said forth dielectric layer and coupled to said second RDL;
forming a fifth dielectric layer formed around said third die; and providing a plastic cover enclosed said first, second and third dice.

20. The method of claim 19, further comprising a step of providing passive device on said forth dielectric layer.

21. The method of claim 19, wherein said third die is formed by flip chip configuration.

22. The method of claim 19, wherein said third die is attached on said forth dielectric layer, and a third RDL is formed over said fifth dielectric layer and coupled to said second RDL.

23. The method of claim 19, wherein one of said first, second, third, forth and fifth dielectric layers includes an elastic dielectric layer

24. The method of claim 19, wherein one of said first, second, third, forth and fifth dielectric layers comprises a silicone dielectric based material, BCB or PI.

25. The method of claim 24, wherein said silicone dielectric based material comprises siloxane polymers (SINR), silicon oxide, silicon nitride, or composites thereof.

26. The method of claim 19, wherein one of said first, second, third, forth and fifth dielectric layers comprises a photosensitive layer.

27. The method of claim 19, wherein one of said first and second RDL is made from an alloy comprising Ti/Cu/Aul alloy or Ti/Cu/Ni/Au alloy.

28. The method of claim 19, wherein the material of said substrate includes epoxy type FR5, FR4, BT, PCB (print circuit board, glass, ceramic, silicon, alloy or metal.

29. The method of claim 28, wherein the material of said substrate includes Alloy42 (42% Ni-58% Fe) or Kovar (29% Ni-17% Co-54% Fe).
